(19) United States
(12) Patent Application Publication
(10) Pub. No.: US 2012/0002708 A1
(43) Pub. Date: Jan. 5, 2012

(54) DEVICE METHOD AND SYSTEM FOR TRANSMISSION AND RECEPTION OF DATA

(76) Inventors: Shay Freundlich, Sunnyvale, CA (US); Zvi Reznic, Tel Aviv (IL); Michael Itai Itnati, Ramat Gan (IL)

(21) Appl. No.: 12/998,791

(22) PCT Filed: Dec. 3, 2009
(86) PCT No.: PCT/IB09/55488

§ 371 Date: Jul. 12, 2011

Related U.S. Application Data
(60) Provisional application No. 61/119,830, filed on Dec. 4, 2008.

(51) Int. Cl. H04B 1/38; H03D 1/24; H03K 9/00; H04L 27/00; H03C 1/52

(52) U.S. Cl. 375/220; 375/295; 375/300; 375/316; 375/320

(57) ABSTRACT

Disclosed is a method, circuit and system for transmission and reception of data, including video data. There is provided a multi-constellation data to symbol mapping logic, circuit or module integral with or otherwise functionally associated with a transmitter and a corresponding multi-constellation symbol to data de-mapping logic, circuit or module integral or otherwise functionally associated with a receiver. The multi-constellation mapping and corresponding de-mapping logic, circuit or module may be characterized by a non-uniform distribution of symbols, and optionally may be characterized by a set of symbol clusters, wherein symbol clusters are of the same or varying sizes and may be spaced either at uniform or non-uniform distances from one another.

### FIELD OF THE INVENTION

Some embodiments relate generally to the field of wireless communication and, more particularly, to a device, method and system for transmission and reception of data.

### BACKGROUND

Wireless communication has rapidly evolved over the past decades. Even today, when high performance and high bandwidth wireless communication equipment is made available there is demand for even higher performance at a higher data rates, which may be required by more demanding applications.

Video signals may be generated by various video sources, for example, a computer, a game console, a Video Cassette Recorder (VCR), a Digital-Versatile-Disc (DVD), a Blu-ray (BR) disk player, or any other suitable video source. In many houses, for example, video signals are received through cable or satellite links at a Set-Top Box (STB) located at a fixed point.

In many cases, it may be desired to place a screen or projector at a location in a distance of at least a few meters from the video source. This trend is becoming more common as flat-screen displays, e.g., plasma or Liquid Crystal Display (LCD) televisions are hung on a wall. Connection of such a display or projector to the video source through cables is generally undesired for aesthetic reasons and/or installation convenience. Thus, wireless transmission of the video signals from the video source to the screen is preferred.

WHDI—Wireless Home Digital Interface is a standard for wireless high-definition video connectivity between a video source (e.g. cable box) and video sink (e.g. display). It provides a high-quality, uncompressed wireless link which can support delivery of equivalent video data rates of up to 3 Gbit/s (including uncompressed 1080p) in a 40 MHz channel within the 5 GHz unlicensed band. Equivalent video data rates of up to 1.5 Gbit/s (including uncompressed 1080i and 720p) can be delivered on a single 20 MHz channel in the 5 GHz unlicensed band, conforming to worldwide 5 GHz spectrum regulations. Range is beyond 100 feet (30 m), through walls, and latency is less than one millisecond.

### SUMMARY OF THE INVENTION

The present invention is a method, circuit and system for transmission and reception of data, including video data. According to some embodiments of the present invention, there may be provided a multi-constellation data to symbol mapping circuit, logic, or module integral with or otherwise functionally associated with a transmitter. According to further embodiments of the present invention, there may be provided a corresponding multi-constellation symbol to data de-mapping circuit, logic or module integral or otherwise functionally associated with a receiver. The multi-constellation mapping and corresponding de-mapping logic, circuit or module may be characterized by a non-uniform distribution of symbols, and optionally may be characterized by a set of symbol clusters, wherein symbol clusters are of the same or varying sizes (i.e. number of symbols) and symbol density (i.e. spacing between symbols), and may be spaced either at uniform or non-uniform distances from one another.

According to yet further embodiments of the present invention, there may be provided a primary cluster of symbols centered around an origin of a complex plane. There may further be provided one or more secondary symbol clusters positioned at a distance from an outer periphery of the primary cluster. It should be understood that a symbol cluster, as described herein, may be considered and/or referred to as a symbol constellation. Thus, symbol mapping and de-mapping logic, circuits and modules referencing a complex symbol plane composed of multiple symbol clusters may be considered and/or referred to as a multi-constellation mapping and de-mapping logic, circuits and modules.

According to some embodiments of the present invention, there may be provided a transmitter, such as: (1) a quadrature amplitude modulation (QAM) based transmitter, (2) an orthogonal frequency-division multiplexing (OFDM) based transmitter, or (3) any other transmitter adapted to transmit data using transmission symbols. According to further embodiments of the present invention relating to video transmission, the transmission symbols may be comprised of coefficients (e.g. frequency coefficients) derived from or otherwise associated with a block of video pixels, or a portion thereof, after a de-correlating transformation. According to some embodiments of the present invention, zero-value (i.e. DC) coefficients, or near DC coefficients may be represented in a coarse, (i.e. digital) manner. According to further embodiments of the present invention, the DC coefficients may be represented as one or more of a plurality of constellation points of a symbol by performing a quantization on their values and mapping them. According to some embodiments of the present invention, relatively higher frequency coefficients and the quantization errors of the DC and the near DC components may be mapped as fine-constellation points thus providing the fine granularity (i.e. analog) values that at an extreme fineness provides for a continuous representation of these values.

Further details with regard to methods and systems of uncompressed, wireless transmission of video are described in U.S. patent application Ser. No. 11/551,641 which application is hereby incorporated by reference in its entirety.

According to some embodiments of the present invention, fine-constellation points may be mapped in a predefined Cartesian coordinate system. According to further embodiments of the present invention, a predefined Cartesian coordinate system may be a complex plane. According to further embodiments of the present invention, the higher frequency coefficients and the quantization errors of the DC and the near DC components may be grouped in pairs, positioning each pair at a point in the complex plane (e.g. as the real and imaginary values of a complex number).

The fine-constellation points may be considered and/or referred to as symbols. Thus, a group of fine-constellation points may be considered and/or referred to as a symbol cluster.

According to some embodiments of the present invention, a primary symbol cluster may be centered around a single point on an axis of the coordinate system (i.e. axis point). According to further embodiments of the present invention, an axis point may be the origin of the coordinate system. According to some embodiments of the present invention, a primary symbol cluster may be uniformly distributed around an axis of the coordinate system. According to further embodiments of the present invention, an axis of the coordinate system may include an axis running diagonally through at least one axis of the coordinate plane.

According to some embodiments of the present invention, a primary symbol cluster may comprise at least 30% of a complete set of symbols. According to further embodiments of the present invention, a primary symbol cluster may comprise at least 50% of a complete set of symbols. According to further embodiments of the present invention, a primary symbol cluster may comprise at least 60% of a complete set of symbols. According to further embodiments of the present invention, a primary symbol cluster may comprise at least 70% of a complete set of symbols.

According to some embodiments of the present invention, a secondary symbol cluster may be distributed around 2 or more points on an axis of the coordinate system (i.e. pilot points).

According to some embodiments of the present invention, a plurality of secondary symbol clusters may be distributed around a plurality of predefined digital constellation points. According to further embodiments of the present invention, a predefined digital constellation may be a Quadrature Amplitude Modulation (QAM) constellation, a Phase Shift Keying (PSK) constellation, and/or a Frequency Shift Keying (FSK) constellation.

According to some embodiments of the present invention, fine constellation points may be considered distributed around a point or axis when they are mapped within a distance to the point or axis less than or equal to 5% of a scale of the coordinate system.

According to some embodiments of the present invention, a spectral power distribution for a QAM/OFDM transmitter is substantially non-flat, indicating a non-even power distribution across frequencies of the transmitter's effective frequency band. Substantially non-flat frequency domain power distribution according to some embodiments may be characterized by a substantially varied power distribution within a sub-band and/or between adjacent sub-bands of the transmitter's effective frequency band.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 shows an exemplary video source transceiver and video sink transceiver arrangement, according to some embodiments of the present invention;

FIG. 2 is a functional block diagram of an exemplary OFDM transmitter circuit according to some embodiments of the present invention where the transmitter includes a multi-constellation mapping scheme;

FIG. 3 is a functional block diagram of an exemplary OFDM receiver circuit according to some embodiments of the present invention where the receiver includes a de-mapping and symbol detecting scheme;

FIG. 4A is an illustration of a multi-constellation map according to some embodiments of the present invention where the map includes at least one primary constellation centered around an axis of the coordinate plane;

FIG. 4B is an illustration of a multi-constellation map according to some embodiments of the present invention where the map includes an elliptical primary constellation centered around an axis running diagonally through at least one axis of the coordinate plane;

FIGS. 5A and 5B are a set of spectral power graphs of a 64 QAM WLAN transmitter, transmitting a 54 megabit-per-second signal centered at 5 Gigahertz (prior art);

FIGS. 6A-6F are a set of exemplary spectral power graphs of a transmitter according to some embodiments of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION

In the following detailed description, numerous specific details are set forth in order to provide a thorough understanding of some embodiments. However, it will be understood by persons of ordinary skill in the art that some embodiments may be practiced without these specific details. In other instances, well-known methods, procedures, components, units and/or circuits have not been described in detail so as not to obscure the discussion.

Unless specifically stated otherwise, as apparent from the following discussions, it is appreciated that throughout the specification discussions utilizing terms such as “processing”, “computing”, “calculating”, “determining”, or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices. In addition, the term “plurality” may be used throughout the specification to describe two or more components, devices, elements, parameters and the like.

It should be understood that some embodiments may be used in a variety of applications. Although embodiments of the invention are not limited in this respect, one or more of the methods, devices and/or systems disclosed herein may be used in many applications, e.g., civil applications, military applications, medical applications, commercial applications, or any other suitable application. In some demonstrative embodiments the methods, devices and/or systems disclosed herein may be used in the field of consumer electronics, for example, as part of any suitable television, video Accessories, Digital-Versatile-Disc (DVD), multimedia projectors, Audio and/or Video (A/V) receivers/transmitters, gaming consoles, video cameras, video recorders, portable media players, cell phones, mobile devices, and/or automobile A/V accessories. In some demonstrative embodiments the methods, devices and/or systems disclosed herein may be used in the field of Personal Computers (PC), for example, as part of any suitable desktop PC, notebook PC, monitor, and/or PC accessories. In some demonstrative embodiments the methods, devices and/or systems disclosed herein may be used in the field of professional A/V, for example, as part of any suitable camera, video camera, and/or A/V accessories. In some demonstrative embodiments the methods, devices and/or systems disclosed herein may be used in the medical field, for example, as part of any suitable endoscopy device and/or system, medical video monitor, and/or medical accessories. In some demonstrative embodiments the methods, devices and/or systems disclosed herein may be used in the field of security and/or surveillance, for example, as part of any suitable security camera, and/or surveillance equipment. In some demonstrative embodiments the methods, devices and/or systems disclosed herein may be used in the fields of military, defense, digital signage, commercial displays, retail accessories, and/or any other suitable field or application.

Although embodiments of the invention are not limited in this respect, one or more of the methods, devices and/or systems disclosed herein may be used to wirelessly transmit video signals, for example, High-Definition-Television (HDTV) signals, between at least one video source and at least one video destination. In other embodiments, the methods, devices and/or systems disclosed herein may be used to transmit, in addition to or instead of the video signals, any other suitable signals, for example, any suitable multimedia signals, e.g., audio signals, between any suitable multimedia source and/or destination.

Although some demonstrative embodiments are described herein with relation to wireless communication including video information, some embodiments may be implemented to perform wireless communication of any other suitable information, for example, multimedia information, e.g., audio information, in addition to or instead of the video information. Some embodiments may include, for example, a method, device and/or system of performing wireless communication of A/V information, e.g., including audio and/or video information. Accordingly, one or more of the devices, systems and/or methods described herein with relation to video information may be adapted to perform wireless communication of A/V information.

Some demonstrative embodiments may be implemented to communicate wireless-video signals over a wireless-video communication link, as well as Wireless-Local-Area-Network (WLAN) signals over a WLAN link. Such implementation may allow a user, for example, to play a movie, e.g., on a laptop computer, and to wirelessly transmit video signals corresponding to the movie to a video destination, e.g., a screen, while maintaining a WLAN connection, e.g., with the Internet and/or one or more other devices connected to a WLAN network. In one example, video information corresponding to the movie may be received over the WLAN network, e.g., from the Internet.

According to some embodiments of the present invention, there may be a transmitter comprising a data to symbol mapping circuit adapted to convert source data into a transmission symbol using a non-uniform geometric distribution of symbols. According to further embodiments of the present invention, the non-uniform symbol distribution may include two or more clusters/constellations of symbols spaced apart from one another.

According to some embodiments of the present invention, the clusters/constellations of symbols may have the same number of symbols or a varied number of symbols.

According to some embodiments of the present invention, the clusters/constellations of symbols may have uniform spacing between the symbols or non-uniform spacing between the symbols.

According to some embodiments of the present invention, the non-uniform symbol distribution may have uniform spacing between the clusters/constellations of symbols or non-uniform spacing between the clusters/constellations of symbols.

According to some embodiments of the present invention, the clusters/constellations of symbols may comprise a primary symbol cluster/constellation around an origin of a complex plane. According to further embodiments of the present invention, the primary cluster/constellation may include a percentage of the total symbols ranging from 30 percent and 70 percent. According to further embodiments of the present invention, the clusters/constellations of symbols may comprise one or more secondary clusters/constellations of symbols at a distance from an outer periphery of the primary symbol cluster/constellation.

According to some embodiments of the present invention, a geometric proximity between two symbols on the complex plane may be correlated with a statistical proximity between the data sets each of the two symbols represent.

According to some embodiments of the present invention, the transmitter may have a substantially non-flat frequency power distribution across frequencies of an effective frequency band. According to further embodiments of the present invention, the substantially non-flat frequency power distribution may include an overall choppiness and/or roughness within all the sub-bands of the effective frequency band. According to further embodiments of the present invention, the substantially non-flat frequency power distribution may include a stop-band (i.e. a low spectral power sub-band) within a baseband sub-band. According to further embodiments of the present invention, the substantially non-flat frequency power distribution may include a sudden peak in between a sideband and a baseband sub-band. According to further embodiments of the present invention, the substantially non-flat frequency power distribution may include a sudden valley in between a sideband and a baseband sub-band.

According to some embodiments of the present invention, source data may be video based data. According to further embodiments of the present invention, video based data may be wireless home digital interface (WHDI) based data.

According to some embodiments of the present invention, the transmitter may be adapted to be a quadrature amplitude modulation (QAM) transmitter. According to further embodiments of the present invention, the transmitter may be adapted to be an orthogonal frequency-division multiplexing (OFDM) transmitter.

According to some embodiments of the present invention, there may be a receiver comprising a symbol to data de-mapping circuit adapted to convert a transmission symbol from a non-uniform geometric distribution of symbols into sink data. According to further embodiments of the present invention, the non-uniform symbol distribution may include two or more clusters/constellations of symbols spaced apart from one another.

According to some embodiments of the present invention, the clusters/constellations of symbols may have the same number of symbols or a varied number of symbols.

According to some embodiments of the present invention, the clusters/constellations of symbols may have uniform spacing between the symbols or a non-uniform spacing between the symbols.

According to some embodiments of the present invention, the non-uniform symbol distribution may have uniform spacing between the clusters/constellations of symbols or non-uniform spacing between the clusters/constellations of symbols.

According to some embodiments of the present invention, the clusters/constellations of symbols may comprise a primary symbol cluster/constellation around an origin of a complex plane. According to further embodiments of the present invention, the primary cluster/constellation may include a percentage of the total symbols ranging from 30 percent and 70 percent. According to further embodiments of the present invention, the clusters/constellations of symbols may comprise one or more secondary clusters/constellations of symbols at a distance from an outer periphery of the primary symbol cluster/constellation.

According to some embodiments of the present invention, a geometric proximity between two symbols on the complex plane may be correlated with a statistical proximity between the data sets each of the two symbols represent.

According to some embodiments of the present invention, sink data may be video based data. According to further embodiments of the present invention, video based data may be wireless home digital interface (WHDI) based data.

According to some embodiments of the present invention, the receiver may be a quadrature amplitude modulation (QAM) receiver. According to further embodiments of the present invention, the receiver may be an orthogonal frequency-division multiplexing (OFDM) receiver.

According to some embodiments of the present invention, there may be a video source transceiver comprising a video source interface adapted to receive video based data from a functionally associated video data source, a data to symbol mapping circuit adapted to convert the video based data into transmission symbols using a non-uniform geometric distribution of symbols, and a downlink transmitter circuit adapted to transmit the transmission symbols. According to further embodiments of the present invention, the non-uniform symbol distribution may include two or more clusters/constellations of symbols spaced apart from one another.

According to some embodiments of the present invention, the clusters/constellations of symbols may have the same number of symbols or a varied number of symbols.

According to some embodiments of the present invention, the clusters/constellations of symbols may have uniform spacing between the symbols or non-uniform spacing between the symbols.

According to some embodiments of the present invention, the non-uniform symbol distribution may have uniform spacing between the clusters/constellations of symbols or non-uniform spacing between the clusters/constellations of symbols.

According to some embodiments of the present invention, the clusters/constellations of symbols may comprise a primary symbol cluster/constellation around an origin of a complex plane. According to further embodiments of the present invention, the primary cluster/constellation may include a percentage of the total symbols ranging from 30 percent and 70 percent. According to further embodiments of the present invention, the clusters/constellations of symbols may comprise one or more secondary clusters/constellations of symbols at a distance from an outer periphery of the primary symbol cluster/constellation.

According to some embodiments of the present invention, a geometric proximity between two symbols on the complex plane may be correlated with a statistical proximity between the data sets each of the two symbols represent.

According to some embodiments of the present invention, the transceiver may have a substantially non-flat frequency power distribution across frequencies of an effective frequency band. According to further embodiments of the present invention, the substantially non-flat frequency power distribution may include an overall choppiness and/or roughness within all the sub-bands of the effective frequency band. According to further embodiments of the present invention, the substantially non-flat frequency power distribution may include a stop-band within a baseband sub-band. According to further embodiments of the present invention, the substantially non-flat frequency power distribution may include a sudden peak in between a sideband and a baseband sub-band. According to further embodiments of the present invention, the substantially non-flat frequency power distribution may include a sudden valley in between a sideband and a baseband sub-band.

According to some embodiments of the present invention, source data may be video based data. According to further embodiments of the present invention, video based data may be wireless home digital interface (WHDI) based data.

According to some embodiments of the present invention, the transceiver may be adapted to be a quadrature amplitude modulation (QAM) transceiver. According to further embodiments of the present invention, the transceiver may be adapted to be an orthogonal frequency-division multiplexing (OFDM) transceiver.

According to some embodiments of the present invention, there may be a video sink transceiver comprising a downlink receiver circuit adapted to receive a transmission symbol based data signal, a symbol to data de-mapping circuit adapted to convert the transmission symbols from a non-uniform geometric distribution of symbols into sink data, and a video sink interface adapted to transmit the sink data to a functionally associated video data sink. According to further embodiments of the present invention, the non-uniform symbol distribution may include two or more clusters/constellations of symbols spaced apart from one another.

According to some embodiments of the present invention, the clusters/constellations of symbols may have the same number of symbols or a varied number of symbols.

According to some embodiments of the present invention, the clusters/constellations of symbols may have uniform spacing between the symbols or a non-uniform spacing between the symbols.

According to some embodiments of the present invention, the non-uniform symbol distribution may have uniform spacing between the clusters/constellations of symbols or non-uniform spacing between the clusters/constellations of symbols.

According to some embodiments of the present invention, the clusters/constellations of symbols may comprise a primary symbol cluster/constellation around an origin of a complex plane. According to further embodiments of the present invention, the primary cluster/constellation may include a percentage of the total symbols ranging from 30 percent and 70 percent. According to further embodiments of the present invention, the clusters/constellations of symbols may comprise one or more secondary clusters/constellations of symbols at a distance from an outer periphery of the primary symbol cluster/constellation.

According to some embodiments of the present invention, a geometric proximity between two symbols on the complex plane may be correlated with a statistical proximity between the data sets each of the two symbols represent.

According to some embodiments of the present invention, sink data may be video based data. According to further embodiments of the present invention, video based data may be wireless home digital interface (WHDI) based data.

According to some embodiments of the present invention, the transceiver may be a quadrature amplitude modulation (QAM) transceiver. According to further embodiments of the present invention, the transceiver may be an orthogonal frequency-division multiplexing (OFDM) transceiver.

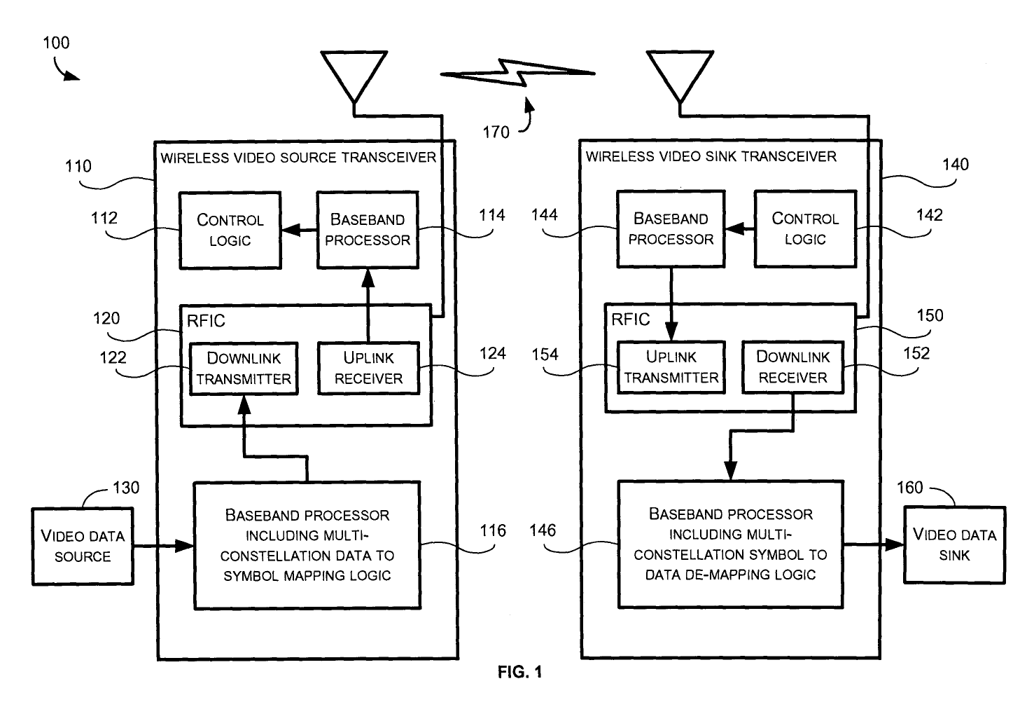

Turning now to FIG. 1, there is shown a functional block diagram of an exemplary video source transceiver and video sink transceiver arrangement (100), according to some embodiments of the present invention.

According to some embodiments of the present invention, a wireless video source transceiver (110) may include a radio-frequency integrated chip (RFIC) (120) to transmit and receive data signals along a functionally associated antenna. According to further embodiments of the present invention, the RFIC may include a downlink transmitter (122) for transmitting downlink data signals and an uplink receiver (124) for receiving uplink data signals.

According to some embodiments of the present invention, the wireless video source transceiver (110) may include a baseband processor (114) to process control signals received via the uplink receiver (124) and send the data to a functionally associated control circuit and/or processor (112). According to some embodiments of the present invention, the wireless video source transceiver (110) may include a baseband processor including multi-constellation data to symbol mapping logic (116) to take incoming video data signals from a functionally associated video data source (130) and process the data for downlink transmission, via the downlink transmitter (122), to a functionally associated wireless video sink transceiver (140).

According to some embodiments of the present invention, a wireless video sink transceiver (140) may include a RFIC chip (150) to transmit and receive data signals along a functionally associated antenna. According to further embodiments of the present invention, the RFIC may include a downlink receiver (152) for receiving downlink data signals and an uplink transmitter (154) for transmitting uplink data signals.

According to some embodiments of the present invention, the wireless video sink transceiver (140) may include a baseband processor (144) to process control data received from a functionally associated control circuit and/or processor (142) and send the control data to the uplink transmitter (154). According to some embodiments of the present invention, the wireless video sink transceiver (140) may include a baseband processor including multi-constellation symbol to data de-mapping logic (146) to take video data signals received, via the downlink receiver (152), from a functionally associated wireless video source transceiver (110) and process the data for a functionally associated video data sink (160).

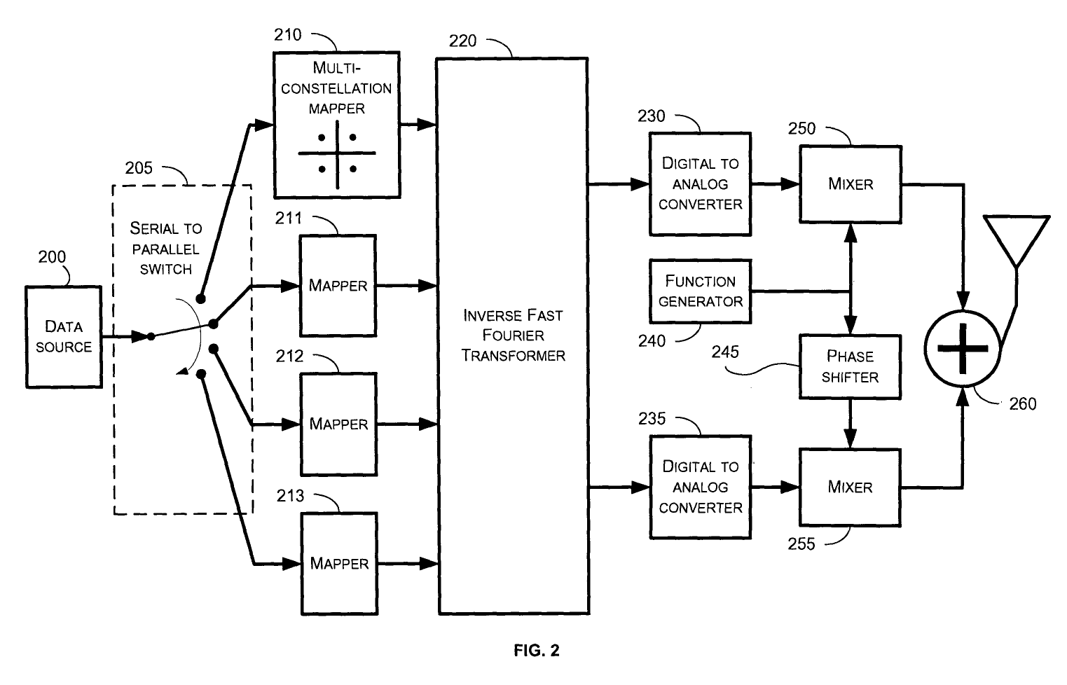

Turning now to FIG. 2, there is shown a functional block diagram of an exemplary OFDM transmitter circuit according to some embodiments of the present invention where the transmitter includes a multi-constellation mapping scheme.

According to some embodiments of the present invention, there may be included a serial to parallel switch (205) to take digital data serially from a functionally associated data source (200) and to load the data into a plurality of functionally associated multi-constellation mappers (210-213). According to some embodiments of the present invention, multi-constellation mappers may employ a non-uniform distribution of symbols, optionally characterized by a set of symbol clusters, wherein symbol clusters are of the same or varying sizes (i.e. number of symbols) and symbol density (i.e. spacing between symbols), and may be spaced either at uniform or non-uniform distances from one another. According to further embodiments of the present invention, a data value may be output from each multi-constellation mapper and input as a frequency component, or bin, to a functionally associated Inverse Fast Fourier Transformer (IFFT) (220).

According to further embodiments of the present invention, the IFFT (220) may compute an inverse discrete Fourier transform on the input multi-constellation data and output a set of complex time-domain digital samples. According to further embodiments of the present invention, the real portions of the complex time-domain digital samples may be converted into an analog signal by a functionally associated digital-to-analog converter (230). According to further embodiments of the present invention, the imaginary portions of the complex time-domain digital samples may be converted into an analog signal by a functionally associated digital-to-analog converter (235).

According to further embodiments of the present invention, the analog version of the real portions of the complex time-domain digital samples may be input to a mixer (250) to modulate a carrier frequency signal output from a function generator (240). According to further embodiments of the present invention, the analog version of the imaginary portions of the complex time-domain digital samples may be input to a mixer (255) to modulate a carrier frequency signal output from a function generator (240) and shifted 90 degrees by a phase shifter (245). According to further embodiments of the present invention, both modulated carrier frequency signals may be summed by an adder (260) to produce a transmission signal to be sent via a functionally associated antenna.

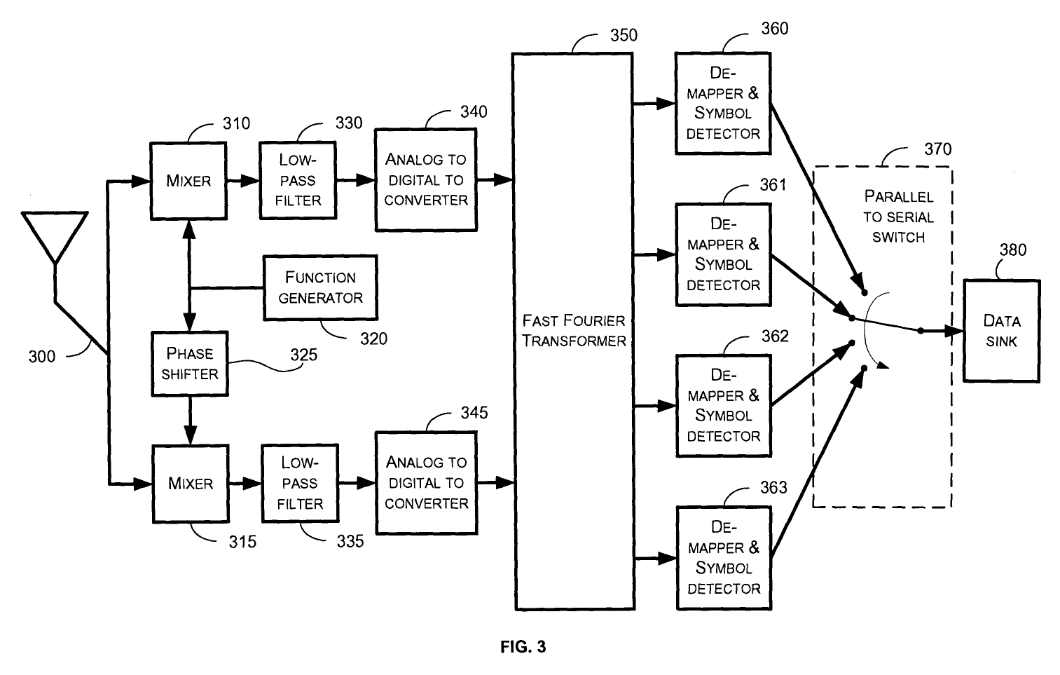

Turning now to FIG. 3, there is shown a functional block diagram of an exemplary OFDM receiver circuit according to some embodiments of the present invention where the receiver includes a de-mapping and symbol detecting scheme.

According to some embodiments of the present invention, there may be included an antenna (300) to receive a transmission signal produced by a functionally associated OFDM transmitter circuit. According to further embodiments of the present invention, the signal may be quadrature-mixed, by a mixer (310), with a carrier frequency signal output from a function generator (320) to produce a baseband version of the transmission signal. According to further embodiments of the present invention, the signal may be filtered by a low-pass filter (330) to remove undesirable components from the baseband signal. According to further embodiments of the present invention, the baseband signal may be converted to digital form by an analog-to-digital converter (340). According to further embodiments of the present invention, the digital values may be input to the Fast Fourier Transformer (FFT) (350) as the real portions of the complex time-domain digital samples.

According to further embodiments of the present invention, the transmission signal may be quadrature-mixed, by a mixer (315), with a carrier frequency signal output from a function generator (320) and shifted 90 degrees by a phase shifter (325) to produce another baseband version of the transmission signal. According to further embodiments of the present invention, the signal may be filtered by a low-pass filter (335) to remove undesirable components from the baseband signal. According to further embodiments of the present invention, the baseband signal may be converted to digital form by an analog-to-digital converter (345). According to further embodiments of the present invention, the digital values may be input to the FFT (350) as the imaginary portions of the complex time-domain digital samples.

According to further embodiments of the present invention, the FFT (350) may perform a discrete Fourier transform on the real portions of the complex time-domain digital samples and the imaginary portions of the complex time-domain digital samples. According to further embodiments of the present invention, the FFT (350) may output several parallel frequency components which are input to de-mappers & symbol detectors (360-363). According to further embodiments of the present invention, the de-mappers & symbol detectors (360-363) may output digital values representing the original digital data produced by a functionally associated data source (200). According to further embodiments of the present invention, the digital values may be sampled by a parallel to serial switch (370) and delivered serially to a functionally associated data sink (380).

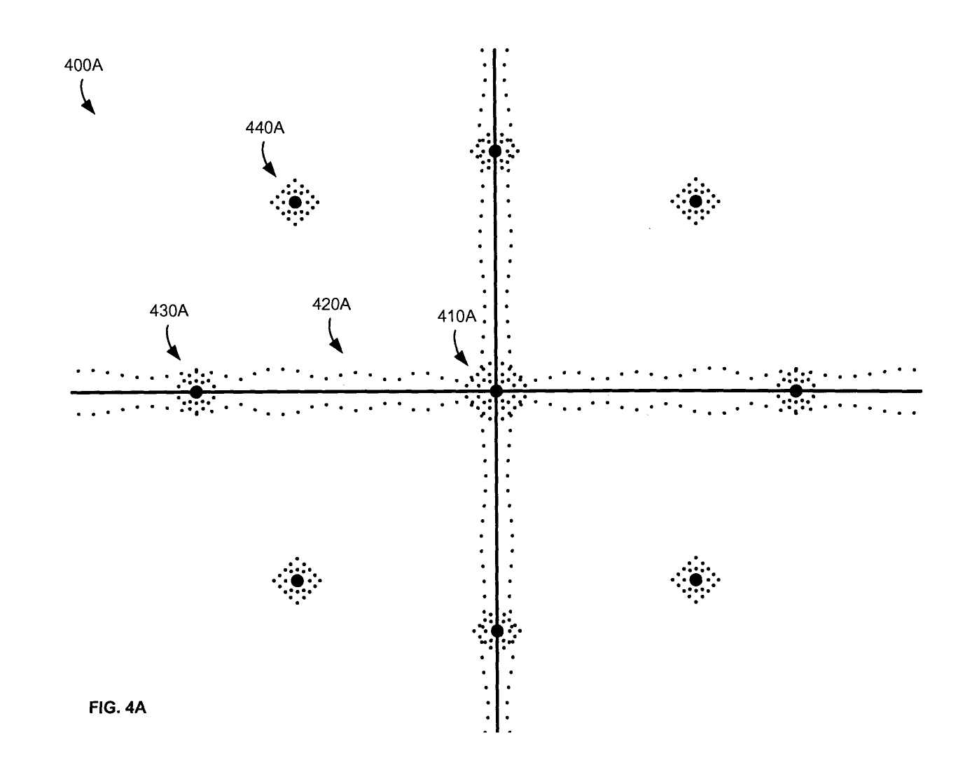

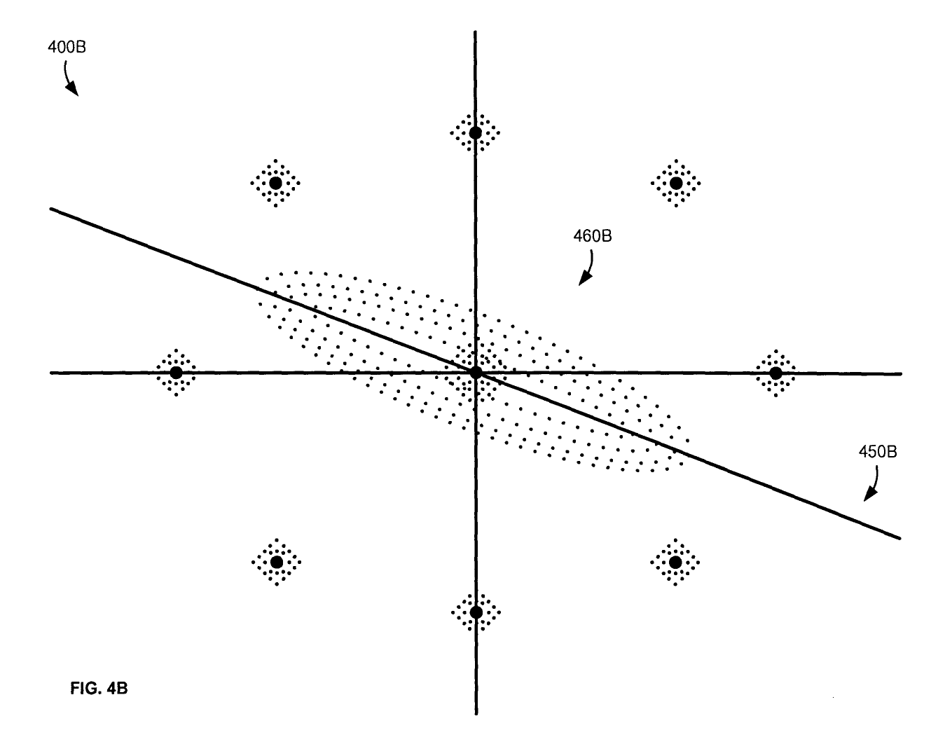

Turning now to FIG. 4A, there is shown a multi-constellation map (400A) according to some embodiments of the present invention where the map includes at least one primary constellation centered around an axis of the coordinate plane.

According to some embodiments of the present invention, the coordinate plane may be a Cartesian coordinate system. According to further embodiments of the present invention, the Cartesian coordinate plane may include a two dimensional complex plane (e.g. a pair of orthogonal axes).

According to some embodiments of the present invention, the multi-constellation map (400A) may include a primary constellation centered around an origin of the coordinate plane (410A). According to further embodiments of the present invention, the multi-constellation map (400A) may include a primary constellation uniformly distributed around an axis of the coordinate plane (420A), e.g. a coordinate axis of the complex plane.

According to some embodiments of the present invention, the multi-constellation map (400A) may include a secondary constellation centered around a point on an axis of the coordinate plane (i.e. a pilot point, 430A). According to further embodiments of the present invention, the multi-constellation map (400A) may include a secondary constellation centered around a predefined digital constellation point (440A) e.g. a Quadrature Amplitude Modulation (QAM) constellation, a Phase Shift Keying (PSK) constellation, and/or a Frequency Shift Keying (FSK) constellation.

Turning now to FIG. 4B, there is shown a multi-constellation map according to some embodiments of the present invention where the map includes an elliptical primary constellation centered around an axis running diagonally through at least one axis of the coordinate plane.

According to some embodiments of the present invention, the coordinate plane may be a Cartesian coordinate system. According to further embodiments of the present invention, the Cartesian coordinate plane may include a two dimensional complex plane (e.g. a pair of orthogonal axes).

According to some embodiments of the present invention, the multi-constellation map (400B) may include an axis running diagonally through the origin of the complex plane (450B). According to further embodiments of the present invention, the multi-constellation map (400B) may include a primary constellation uniformly distributed around the diagonal axis (460B), e.g. a constellation substantially elliptical or circular.

According to some embodiments of the present invention, the multi-constellation map (400B) may include a secondary constellation centered around a pilot point and/or a predefined digital constellation point (e.g. a Quadrature Amplitude Modulation (QAM) constellation, a Phase Shift Keying (PSK) constellation, and/or a Frequency Shift Keying (FSK) constellation).

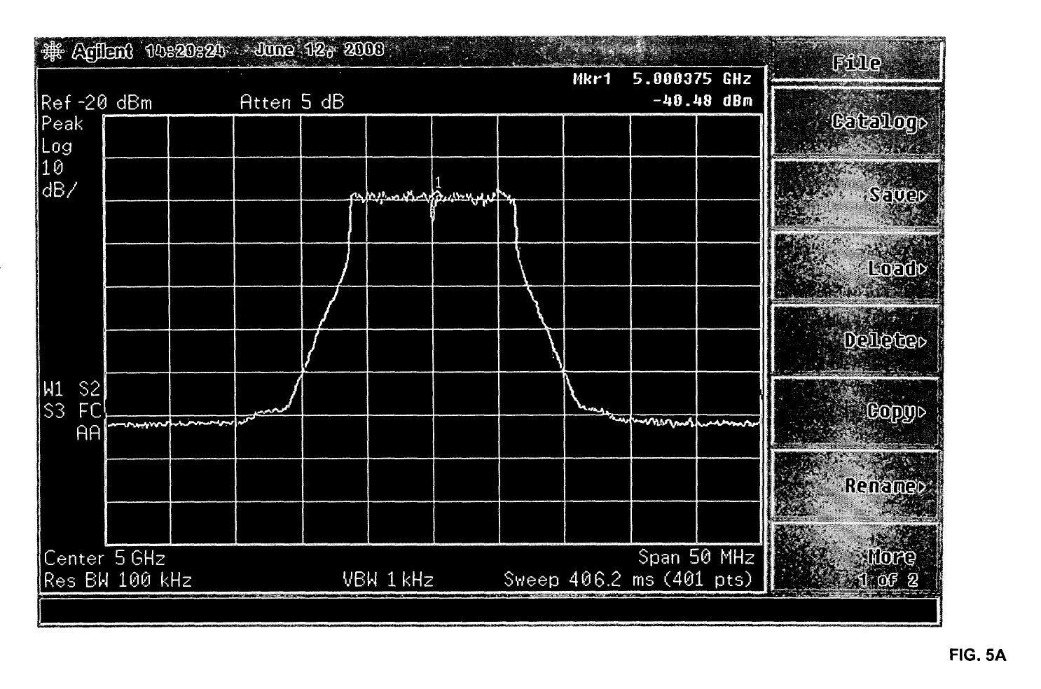

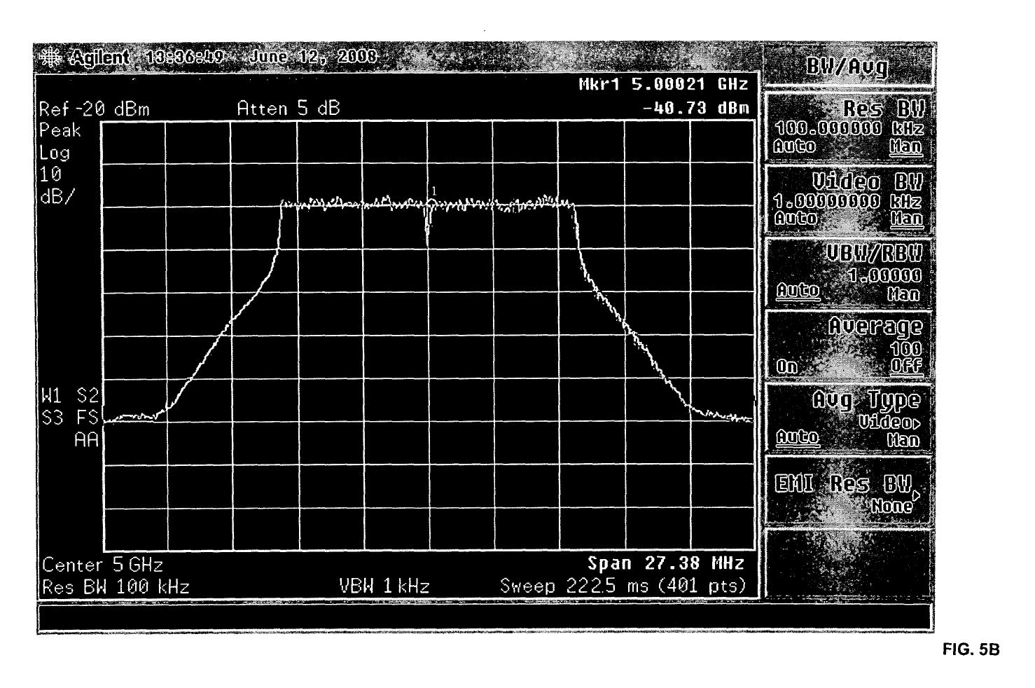

Turning now to FIGS. 5A and 5B, there are shown a set of spectral power graphs of a 64 QAM WLAN transmitter, transmitting a 54 megabit-per-second signal centered at 5 Gigahertz (prior art). The power distribution is substantially flat, indicating an even power distribution across frequencies of the transmitter's effective frequency band.

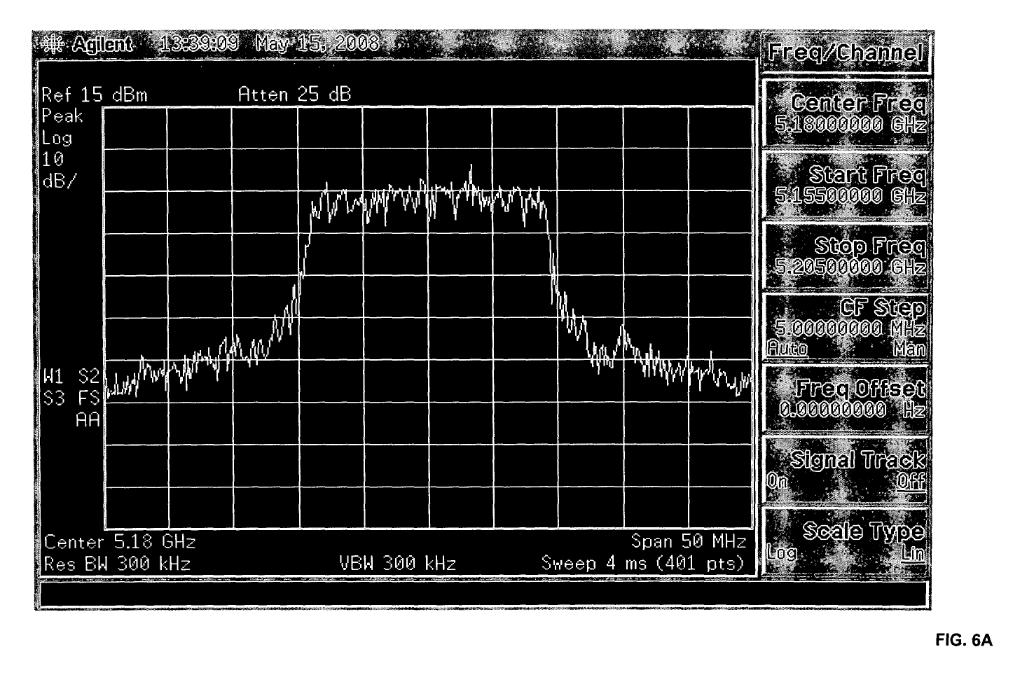

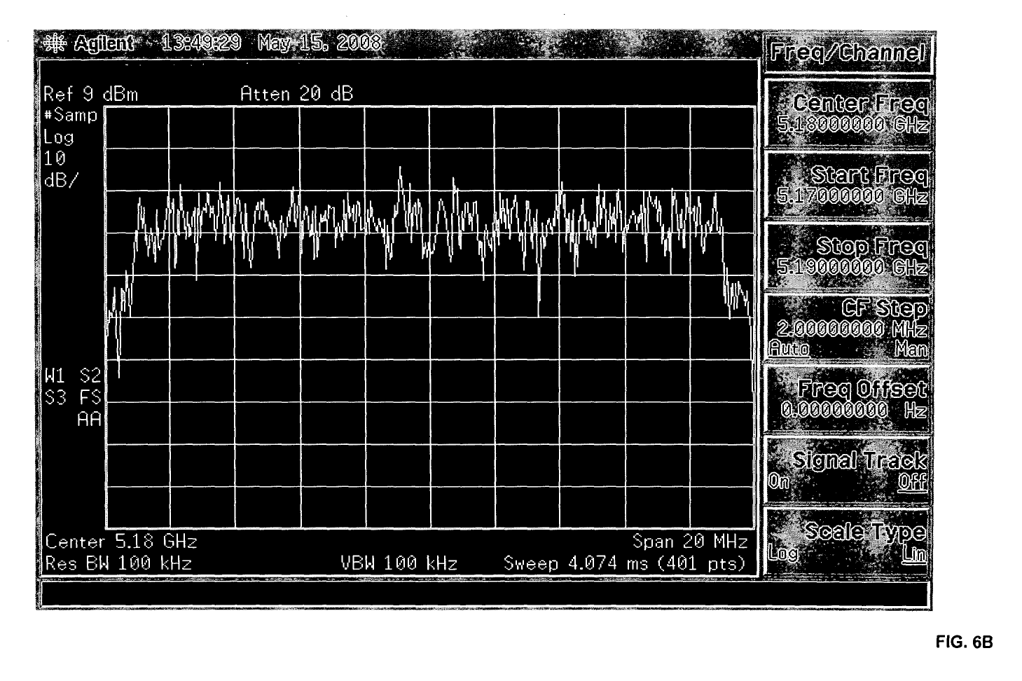

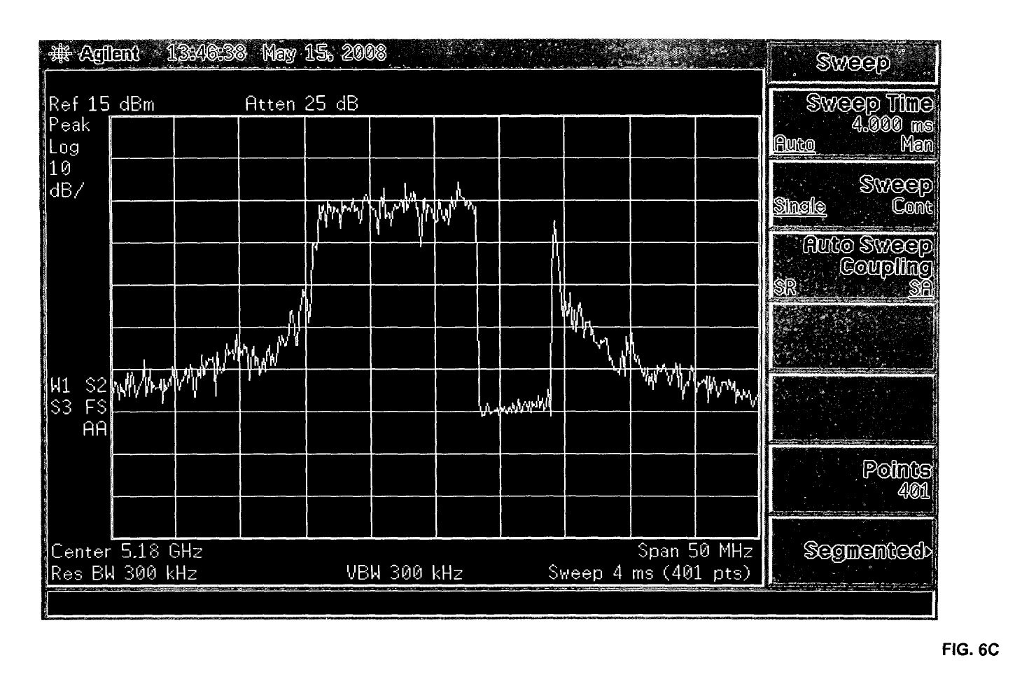

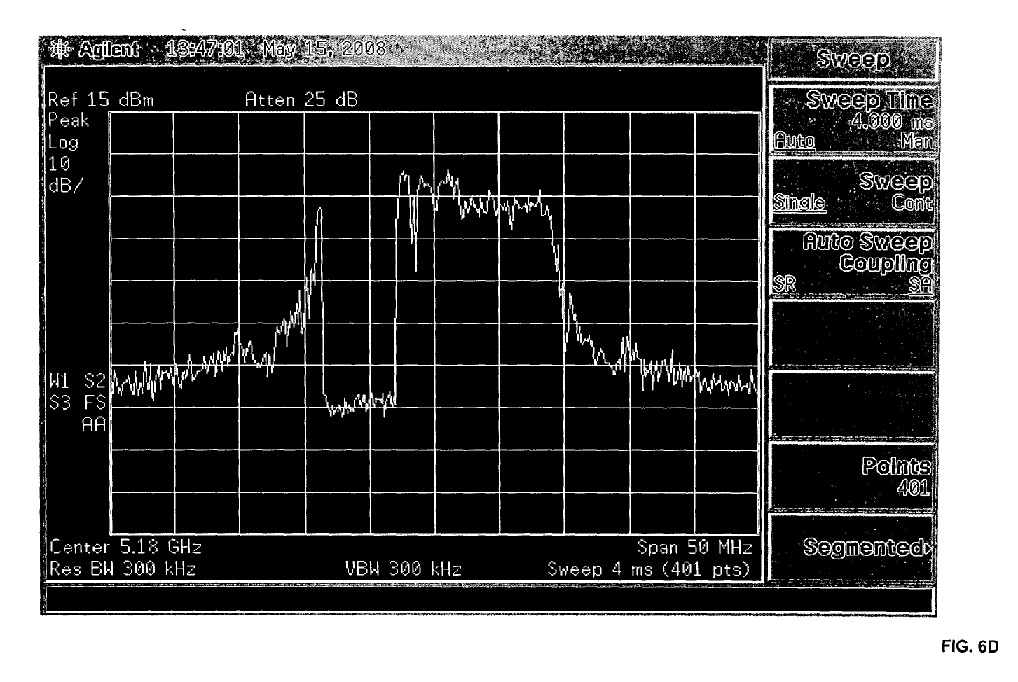

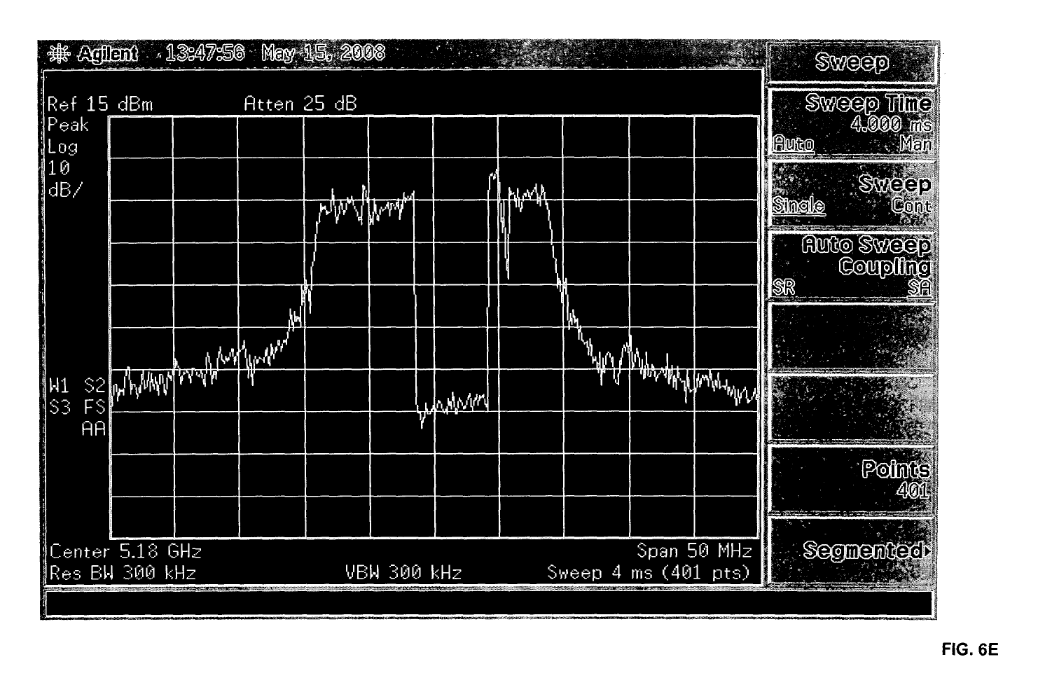

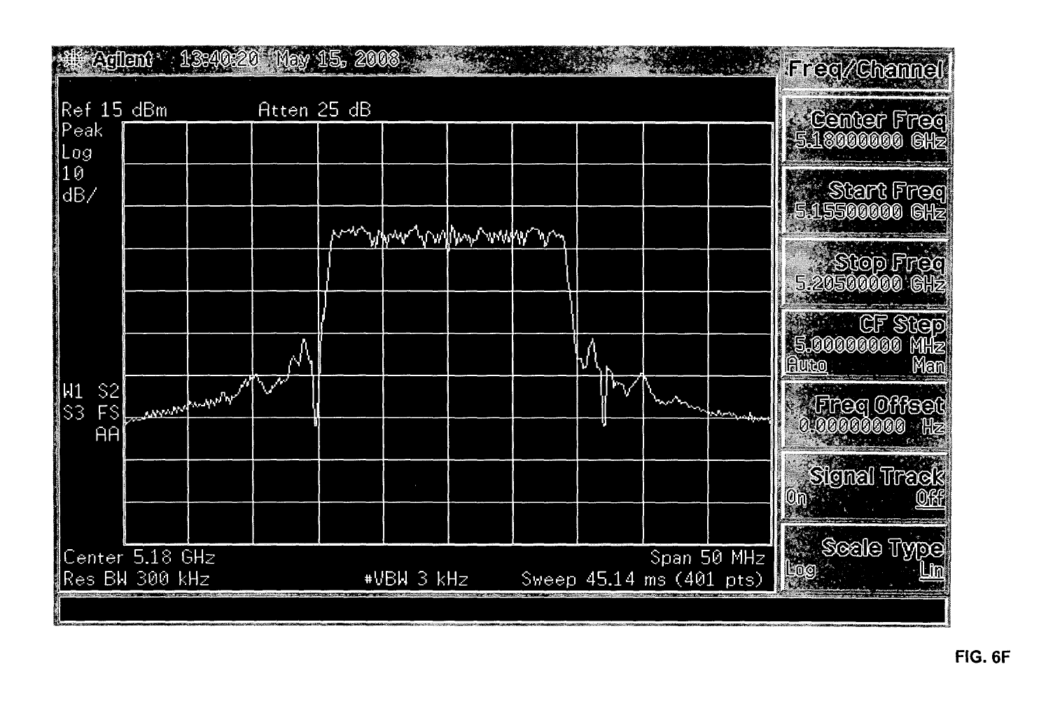

Turning now to FIGS. 6A to 6F, there are shown a set of exemplary spectral power graphs of a transmitter according to some embodiments of the present invention. A spectral power distribution for a QAM/OFDM transmitter according to some embodiments of the present invention is substantially non-flat, indicating a non-even power distribution across frequencies of the transmitter's effective frequency band. Substantially non-flat frequency domain power distribution according to some embodiments may be characterized by a substantially varied power distribution within a sub-band and/or between adjacent sub-bands of the transmitter's effective frequency band.

According to some embodiments of the present invention, a substantially varied power distribution within a sub-band of the transmitter's effective frequency band may be viewed as an overall choppiness and/or roughness within all the sub-bands of the effective frequency band (FIGS. 6A & 6B). According to further embodiments of the present invention, a substantially varied power distribution within a sub-band of the transmitter's effective frequency band may be viewed as a stop-band (i.e. a low spectral power sub-band) within a pass-band (i.e. baseband) sub-band (FIGS. 6C-E).

According to some embodiments of the present invention, a substantially varied power distribution between adjacent sub-bands of the transmitter's effective frequency band may be viewed as a sudden peak and/or valley in between a sideband and a baseband sub-band (FIG. 6F).

Some embodiments of the invention, for example, may take the form of an entirely hardware embodiment, an entirely software embodiment, or an embodiment including both hardware and software elements. Some embodiments may be implemented in software, which includes but is not limited to firmware, resident software, microcode, or the like.

Furthermore, some embodiments of the invention may take the form of a computer program product accessible from a computer-usable or computer-readable medium providing program code for use by or in connection with a computer or any instruction execution system. For example, a computer-usable or computer-readable medium may be or may include any apparatus that can contain, store, communicate, propagate, or transport the program for use by or in connection with the instruction execution system, apparatus, or device.

In some embodiments, the medium may be an electronic, magnetic, optical, electromagnetic, infrared, or semiconductor system (or apparatus or device) or a propagation medium. Some demonstrative examples of a computer-readable medium may include a semiconductor or solid state memory, magnetic tape, a removable computer diskette, a random access memory (RAM), a read-only memory (ROM), a rigid magnetic disk, and an optical disk. Some demonstrative examples of optical disks include compact disk-read only memory (CD-ROM), compact disk-read/write (CD-RAY), and DVD.

In some embodiments, a data processing system suitable for storing and/or executing program code may include at least one processor coupled directly or indirectly to memory elements, for example, through a system bus. The memory elements may include, for example, local memory employed during actual execution of the program code, bulk storage, and cache memories which may provide temporary storage of at least some program code in order to reduce the number of times code must be retrieved from bulk storage during execution.

In some embodiments, input/output or I/O devices (including but not limited to keyboards, displays, pointing devices, etc.) may be coupled to the system either directly or through intervening I/O controllers. In some embodiments, network adapters may be coupled to the system to enable the data processing system to become coupled to other data processing systems or remote printers or storage devices, for example, through intervening private or public networks. In some embodiments, modems, cable modems and Ethernet cards are demonstrative examples of types of network adapters. Other suitable components may be used.

Functions, operations, components and/or features described herein with reference to one or more embodiments, may be combined with, or may be utilized in combination with, one or more other functions, operations, components and/or features described herein with reference to one or more other embodiments, or vice versa.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. A transmitter comprising:
a data to symbol mapping circuit adapted to convert source data into a transmission symbol using a non-uniform geometric distribution of symbols.

2. The transmitter according to claim 1, wherein the non-uniform symbol distribution includes two or more clusters/constellations of symbols spaced apart from one another.

3. The transmitter according to claim 2, wherein the clusters/constellations of symbols have the same number of symbols.

4. The transmitter according to claim 2, wherein the clusters/constellations of symbols have a varied number of symbols.

5. The transmitter according to claim 2, wherein the clusters/constellations of symbols have uniform spacing between the symbols.

6. The transmitter according to claim 2, wherein the clusters/constellations of symbols have non-uniform spacing between the symbols.

7. The transmitter according to claim 2, wherein the non-uniform symbol distribution have uniform spacing between the clusters/constellations of symbols.

8. The transmitter according to claim 2, wherein the non-uniform symbol distribution have non-uniform spacing between the clusters/constellations of symbols.

9. The transmitter according to claim 2, wherein the clusters/constellations of symbols comprises a primary symbol cluster/constellation around an origin of a complex plane.

10. The transmitter according to claim 9, wherein the primary cluster/constellation includes a percentage of the total symbols ranging from 30 percent and 70 percent.

11. The transmitter according to claim 9, wherein the clusters/constellations of symbols comprises one or more secondary clusters/constellations of symbols at a distance from an outer periphery of the primary symbol cluster/constellation.

12. The transmitter according to claim 1, wherein a geometric proximity between two symbols on the complex plane is correlated with a statistical proximity between the data sets each of the two symbols represent.

13. The transmitter according to claim 1, wherein the transmitter has a substantially non-flat frequency power distribution across frequencies of an effective frequency band.

14. The transmitter according to claim 13, wherein the substantially non-flat frequency power distribution includes an overall choppiness and/or roughness within all the sub-bands of the effective frequency band.

15. The transmitter according to claim 13, wherein the substantially non-flat frequency power distribution includes a stop-band within a baseband sub-band.

16. The transmitter according to claim 13, wherein the substantially non-flat frequency power distribution includes a sudden peak in between a sideband and a baseband sub-band.

17. The transmitter according to claim 13, wherein the substantially non-flat frequency power distribution includes a sudden valley in between a sideband and a baseband sub-band.

18. The transmitter according to claim 1, wherein source data is video based data.

19. The transmitter according to claim 18, wherein video based data is wireless home digital interface (WHDI) based data.

20. The transmitter according to claim 1, adapted to be a quadrature amplitude modulation (QAM) transmitter.

21. The transmitter according to claim 1, adapted to be an orthogonal frequency-division multiplexing (OFDM) transmitter.

22. A receiver comprising:
a symbol to data de-mapping circuit adapted to convert a transmission symbol from a non-uniform geometric distribution of symbols into sink data.

23. The receiver according to claim 22, wherein the non-uniform symbol distribution includes two or more clusters/constellations of symbols spaced apart from one another.

24. The receiver according to claim 23, wherein the clusters/constellations of symbols have the same number of symbols.

25. The receiver according to claim 23, wherein the clusters/constellations of symbols have a varied number of symbols.

26. The receiver according to claim 23, wherein the clusters/constellations of symbols have uniform spacing between the symbols.

27. The receiver according to claim 23, wherein the clusters/constellations of symbols have non-uniform spacing between the symbols.

28. The receiver according to claim 23, wherein the non-uniform symbol distribution have uniform spacing between the clusters/constellations of symbols.

29. The receiver according to claim 23, wherein the non-uniform symbol distribution have non-uniform spacing between the clusters/constellations of symbols.

30. The receiver according to claim 23, wherein the clusters/constellations of symbols comprises a primary symbol cluster/constellation around an origin of a complex plane.

31. The receiver according to claim 30, wherein the primary cluster/constellation includes a percentage of the total symbols ranging from 30 percent and 70 percent.

32. The receiver according to claim 30, wherein the clusters/constellations of symbols comprises one or more secondary clusters/constellations of symbols at a distance from an outer periphery of the primary symbol cluster/constellation.

33. The receiver according to claim 22, wherein a geometric proximity between two symbols on the complex plane is correlated with a statistical proximity between the data sets each of the two symbols represent.

34. The receiver according to claim 22, wherein sink data is video based data.

35. The receiver according to claim 34, wherein video based data is wireless home digital interface (WHDI) based data.

36. The receiver according to claim 22, adapted to be a quadrature amplitude modulation (QAM) receiver.

37. The receiver according to claim 22, adapted to be an orthogonal frequency-division multiplexing (OFDM) receiver.

38. A video source transceiver comprising:
a video source interface adapted to receive video based data from a functionally associated video data source;
a data to symbol mapping circuit adapted to convert the video based data into transmission symbols using a non-uniform geometric distribution of symbols; and
a downlink transmitter circuit adapted to transmit the transmission symbols.

39. The transceiver according to claim 38, wherein the non-uniform symbol distribution includes two or more clusters/constellations of symbols spaced apart from one another.

40. The transceiver according to claim 39, wherein the clusters/constellations of symbols have the same number of symbols.

41. The transceiver according to claim 39, wherein the clusters/constellations of symbols have a varied number of symbols.

42. The transceiver according to claim 39, wherein the clusters/constellations of symbols have uniform spacing between the symbols.

43. The transceiver according to claim 39, wherein the clusters/constellations of symbols have non-uniform spacing between the symbols.

44. The transceiver according to claim 39, wherein the non-uniform symbol distribution have uniform spacing between the clusters/constellations of symbols.

45. The transceiver according to claim 39, wherein the non-uniform symbol distribution have non-uniform spacing between the clusters/constellations of symbols.

46. The transceiver according to claim 39, wherein the clusters/constellations of symbols comprises a primary symbol cluster/constellation around an origin of a complex plane.

47. The transceiver according to claim 46, wherein the primary cluster/constellation includes a percentage of the total symbols ranging from 30 percent and 70 percent.

48. The transceiver according to claim 46, wherein the clusters/constellations of symbols comprises one or more secondary clusters/constellations of symbols at a distance from an outer periphery of the primary symbol cluster/constellation.

49. The transceiver according to claim 38, wherein a geometric proximity between two symbols on the complex plane is correlated with a statistical proximity between the data sets each of the two symbols represent.

50. The transceiver according to claim 38, wherein the transmitter has a substantially non-flat frequency power distribution across frequencies of an effective frequency band.

51. The transceiver according to claim 50, wherein the substantially non-flat frequency power distribution includes an overall choppiness and/or roughness within all the sub-bands of the effective frequency band.

52. The transceiver according to claim 50, wherein the substantially non-flat frequency power distribution includes a stop-band within a baseband sub-band.

53. The transceiver according to claim 50, wherein the substantially non-flat frequency power distribution includes a sudden peak in between a sideband and a baseband sub-band.

54. The transceiver according to claim 50, wherein the substantially non-flat frequency power distribution includes a sudden valley in between a sideband and a baseband sub-band.

55. The transceiver according to claim 38, wherein source data is video based data.

56. The transceiver according to claim 55, wherein video based data is wireless home digital interface (WHDI) based data.

57. The transceiver according to claim 38, adapted to be a quadrature amplitude modulation (QAM) transceiver.

58. The transceiver according to claim 38, adapted to be an orthogonal frequency-division multiplexing (OFDM) transceiver.

59. A video sink transceiver comprising:
a downlink receiver circuit adapted to receive a transmission symbol based data signal;
a symbol to data de-mapping circuit adapted to convert the transmission symbols from a non-uniform geometric distribution of symbols into sink data; and
a video sink interface adapted to transmit the sink data to a functionally associated video data sink.

60. The transceiver according to claim 59, wherein the non-uniform symbol distribution includes two or more clusters/constellations of symbols spaced apart from one another.

61. The transceiver according to claim 60, wherein the clusters/constellations of symbols have the same number of symbols.

62. The transceiver according to claim 60, wherein the clusters/constellations of symbols have a varied number of symbols.

63. The transceiver according to claim 60, wherein the clusters/constellations of symbols have uniform spacing between the symbols.

64. The transceiver according to claim 60, wherein the clusters/constellations of symbols have non-uniform spacing between the symbols.

65. The transceiver according to claim 60, wherein the non-uniform symbol distribution have uniform spacing between the clusters/constellations of symbols.

66. The transceiver according to claim 60, wherein the non-uniform symbol distribution have non-uniform spacing between the clusters/constellations of symbols.

67. The transceiver according to claim 60, wherein the clusters/constellations of symbols comprises a primary symbol cluster/constellation around an origin of a complex plane.

68. The transceiver according to claim 67, wherein the primary cluster/constellation includes a percentage of the total symbols ranging from 30 percent and 70 percent.

69. The transceiver according to claim 67 wherein the clusters/constellations of symbols comprises one or more secondary clusters/constellations of symbols at a distance from an outer periphery of the primary symbol cluster/constellation.

70. The transceiver according to claim 59, wherein a geometric proximity between two symbols on the complex plane is correlated with a statistical proximity between the data sets each of the two symbols represent.

71. The transceiver according to claim 59, wherein sink data is video based data.

72. The transceiver according to claim 71, wherein video based data is wireless home digital interface (WHDI) based data.

73. The transceiver according to claim 59, adapted to be a quadrature amplitude modulation (QAM) transceiver.

74. The transceiver according to claim 59, adapted to be an orthogonal frequency-division multiplexing (OFDM) transceiver.
